(19) United States
(12) Patent Application Publication
(10) Pub. No.: US 2024/0193316 A1
(43) Pub. Date: Jun. 13, 2024

(54) RECURSIVE SIMULATED EXECUTION OF DOWNHOLE CUTTING STRUCTURE PERFORMANCE AFTER DRILLING

(71) Applicant: Halliburton Energy Services, Inc., Houston, TX (US)

(72) Inventors: Shilin Chen, Conroe, TX (US); Bradley David Dunbar, Conroe, TX (US); Michael Stephen Pierce, Conroe, TX (US)

(21) Appl. No.: 18/078,809

(22) Filed: Dec. 9, 2022

(51) Int. Cl. G06F 30/13; E21B 49/00

(52) U.S. Cl. CPC G06F 30/13; E21B 49/00

(57) ABSTRACT

A method for downhole cutting structure design. The method comprises executing a first computer-simulated drilling by at least one downhole cutting structure of a wellbore into a subsurface formation based on an original data set that includes at least one drilling parameter and at least one downhole cutting structure attribute associated with an actual drilling of the wellbore using the at least one downhole cutting structure into the subsurface formation. The method comprises recursively performing the following operations until a drilling performance threshold is satisfied, changing at least one of the at least one drilling parameter and the at least one downhole cutting structure attribute in the original data set to create a modified data set and executing a second computer-simulated drilling by the at least one downhole cutting structure of the wellbore into the subsurface formation based and the modified data set.

### FIELD

The disclosure generally relates to drilling of wellbores and more particularly, to drill bit designs used for such drilling.

### BACKGROUND

Various types of downhole cutting structures have been used to form wellbores in different types of subsurface formations. Examples of such cutting structures can include drill bits such as fixed cutter drill bits, drag bits, polycrystalline diamond compact (PDC) drill bits, matrix drill bits, etc. associated with forming oil and gas wells extending through one or more subsurface formations. Fixed cutter drill bits such as a PDC drill bit may include multiple blades that each include multiple cutting elements.

After a downhole cutting structure (e.g., a drill bit) is used in a typical drilling application, the drilling performance of the downhole cutting structure can be used to improve the drilling performance of future wells drilled with a similar downhole cutting structure. The improvement of a downhole cutting structure's drilling performance can reduce costs during drilling operations. The drilling performance can be impacted by several variables including drilling parameters, drill bit design, geological formation properties, drilling fluid properties, and drill bit hydraulics.

### BRIEF DESCRIPTION OF THE DRAWINGS

Embodiments of the disclosure may be better understood by referencing the accompanying drawings.

FIG. 1 depicts an example well system, according to some embodiments.

FIGS. 2A-2B are an overhead view and an isometric view, respectively, of an example drill bit, according to some embodiments.

FIG. 3 depicts a flowchart of example operations to generate a downhole cutting structure design and/or drilling parameters, according to some embodiments.

FIGS. 4A-4E depict example graphs of possible response data, according to some embodiments.

FIGS. 5A-5E depict example graphs of possible subsurface formation properties, according to some embodiments.

FIG. 6 depicts an example graph of the drilling performances, according to some embodiments.

FIG. 7 depicts a flowchart of example operations to calibrate a drilling simulator, according to some embodiments.

FIGS. 8A-8E depict example graphs of sectional data, according to some embodiments.

FIGS. 9A-9C depict example graphs for calibrating the subsurface property, according to some embodiments.

FIG. 10 depicts a flowchart of example operations to generate a base drilling performance, according to some embodiments.

FIG. 11 depicts a flowchart of example operations to generate an updated drilling performance, according to some embodiments.

FIG. 12 depicts an example multi-well system, according to some embodiments.

FIG. 13 depicts an example computer, according to some embodiments.

### DESCRIPTION

The description that follows includes example systems, methods, techniques, and program flows that embody aspects of the disclosure. However, it is understood that this disclosure may be practiced without these specific details. For instance, this disclosure refers to PDC drill bits in illustrative examples. Aspects of this disclosure can also be applied to any other types of drill bits or drilling tools. In other instances, well-known instruction instances, protocols, structures, and techniques have not been shown in detail in order not to obfuscate the description.

In drilling a wellbore with a downhole cutting structure in a subsurface formation, the drilling performance of the downhole cutting structure may be utilized to design future downhole cutting structures for drilling in similar environments. After a wellbore is drilled, some implementations may determine how drilling performance may be further improved if there was an opportunity to drill the same wellbore a second time. For example, example embodiments may include a computer simulation of the drilling performance of the downhole cutting structure. Additionally, this computer simulation of the drilling performance may be repeated with changes in the simulation such as a change in at least one drilling parameter and a change in at least one downhole cutting structure attribute. Thus, as further described below, example embodiments may allow for a better drilling performance and reduced drilling costs. Additionally, example embodiments may enable designs of better downhole cutting structure in terms of efficiency, costs, etc.

For example, at least one drilling parameter (e.g., weight on bit (WOB), rate of penetration (ROP), etc.) set while drilling a wellbore, with at least one downhole cutting structure (e.g., a drill bit, a drill bit and a reamer, a core drill, a stand-alone reamer, a combination of cutting structures, etc.), in a subsurface formation may be obtained after drilling the wellbore. Some implementations may also obtain response data, in accordance with the at least one drilling parameter. The response data may indicate the response of the downhole cutting structure as the downhole cutting structure interacts with the subsurface formation. Some implementations may utilize the response data to determine estimates of one or more properties of the subsurface formation. For example, response by the downhole cutting structure may be used to determine formation compressive strength. Some implementations may also obtain the cutter dull severity of each cutter on the downhole cutting structure after drilling the wellbore.

First, a base drilling performance of this drilling of the wellbore may be determined using a downhole cutting structure drilling simulation. For example, this downhole cutting structure drilling simulation may use these same drilling parameters, estimates of one or more properties of the subsurface formation (e.g., formation compressive strength) and cutter dull severity of each cutter on the downhole cutting structure for this drilling of the wellbore. This downhole cutting structure drilling simulation may then output a base drilling performance.

Next, the downhole cutting structure drilling simulation of this drilling of the wellbore may be repeated but with a change in at least one of the downhole cutting structure attributes (e.g., cutter upgrade, bit design improvement, etc.) and a change in one or more of the drilling parameters to generate a second drilling performance. If the second drilling performance is better than the base drilling performance, the changes in the downhole cutting structure attribute and/or drilling parameters may be accepted. In some implementations, the downhole cutting structure drilling simulation with changes in at least one of the downhole cutting structure attribute and/or the one or more drilling parameters may be repeated until a satisfactory drilling performance is obtained. For example, the downhole cutting structure drilling simulation (with changes in at least one of the downhole cutting structure attribute and/or change in the one or more drilling parameters) may be recursively performed until a drilling performance threshold is satisfied.

In some implementations, downhole cutting structure drilling simulation and the resulting drilling performance may be for a given section (e.g., a range of depth of the wellbore) of the drilling of the wellbore. Thus, in some example embodiments, a digital cutter dull severity may be used to estimate cutter wear and cutter damage in each drilling section. Additionally, downhole cutting structure drilling responses may be used to estimate rock compressive strength in each drilling section. The estimated rock compressive strength can be calibrated in each drilling section. Also, as further described below, example implementations enable drilling performance to be simulated along the drilling depth at each drilling section, where cutter dull severity, drilling parameters, and rock compressive strength may vary between the different drilling sections.

In some implementations, the updated drilling performance may be used to set drilling parameters and/or determine attributes of the downhole cutting structure for a current or future drilling operation. For example, a drilling operation may be initiated, modified, or stopped based on the alarm and recommended mitigation activities. Examples of such wellbore operations may include adjusting a drilling operation plan for a wellbore to be drilled in a similar subsurface formation, adjusting the downhole cutting structure design for a downhole cutting structure to be used in a similar subsurface formation, adjusting the cutter design for a downhole cutting structure to be used in a similar subsurface formation, etc. For instance, the updated drilling performance may indicate the rate of penetration (ROP) of a drill bit through the subsurface formation may increase with an upgraded cutter material. Accordingly, in this example situation, a drill bit (used to drill a wellbore in an approximately similar subsurface formation) may be designed with the upgraded cutter material.

### Example Well System

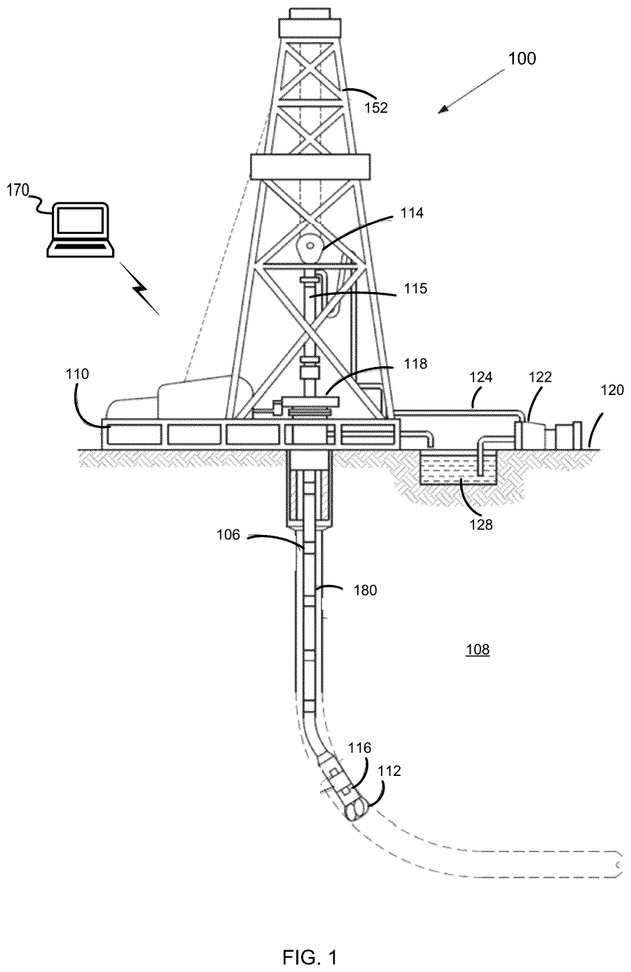

FIG. 1 depicts an example well system, according to some embodiments. In particular, FIG. 1 is a schematic diagram of a well system 100 that includes a drill string 106 having a drill bit 112 disposed in a wellbore 180 for drilling the wellbore 180 in the subsurface formation 108. While depicted for a land-based well system, example embodiments can be used in subsea operations that employ floating or sea-based platforms and rigs. The drill bit 112 is an example downhole cutting structure for which simulation of the downhole cutting structure's drilling performance as described herein can be performed.

The well system 100 may further include a drilling platform 110 that supports a derrick 152 having a traveling block 114 for raising and lowering the drill string 106. The drill string 106 may include, but is not limited to, drill pipe, drill collars, and downhole tools 116. The downhole tools 116 may comprise any of a number of different types of tools including measurement while drilling (MWD) tools, logging while drilling (LWD) tools, mud motors, and others. A kelly 115 may support the drill string 106 as it may be lowered through a rotary table 118. While FIG. 1 is described relative to a drill bit, aspects of the disclosure may be applied to any downhole cutting structure or multiple downhole cutting structures. For instance, the drill bit 112 may include roller cone bits, polycrystalline diamond compact (PDC) bits, natural diamond bits, any hole openers, reamers, coring bits, and the like. As the drill bit 112 rotates, it may crush or cut rock to create and extend a wellbore 180 that penetrates various subterranean formations. The drill bit 112 may be rotated by various methods including rotation by a downhole mud motor and/or via rotation of the drill string 106 from the surface 120 by the rotary table 118. Parameters of drilling the wellbore 180 may be adjusted to increase, decrease, and/or maintain the rate of penetration (ROP) of the drill bit 112 through the subsurface formation 108. Drilling parameters may include weight-on-bit (WOB) and rotations-per-minute (RPM) of the drill string 106. In some embodiments, the drill bit 112 may become dull and lose efficiency, thus requiring more WOB and/or RPM to maintain a target ROP. The downhole tools 116 may obtain response data as the drill bit 112 drills the subsurface formation 108. Response data may include downhole WOB, downhole TOB, downhole RPM, vibrations of the drill bit, etc. A pump 122 may circulate drilling fluid through a feed pipe 124 to the kelly 116, downhole through interior of the drill string 106, through orifices in the drill bit 112, back to the surface 120 via an annulus surrounding the drill string 106, and into a retention pit 128.

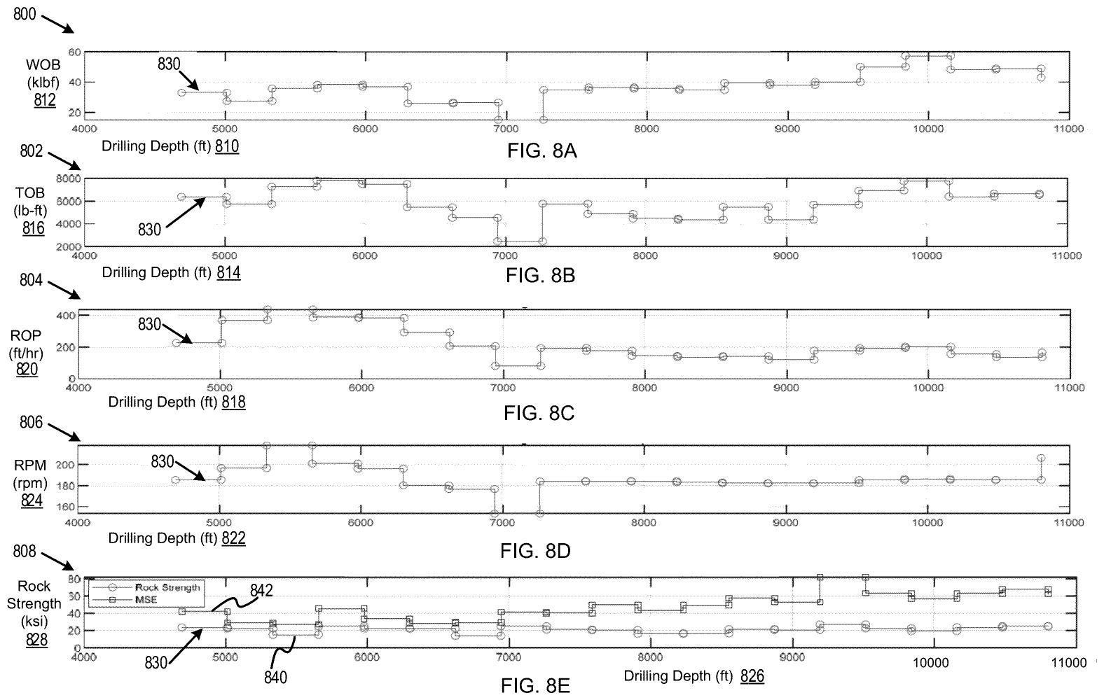

The well system 100 includes a computer 170 that may be communicatively coupled to other parts of the well system 100. The computer 170 can be local or remote to the drilling platform 110. A processor of the computer 170 may perform simulations (as further described below). In some embodiments, the processor of the computer 170 may control drilling operations of the well system 100 or subsequent drilling operations of other wellbores. An example of the computer 170 is depicted in FIG. 8, which is further described below.

### Example Drill Bit

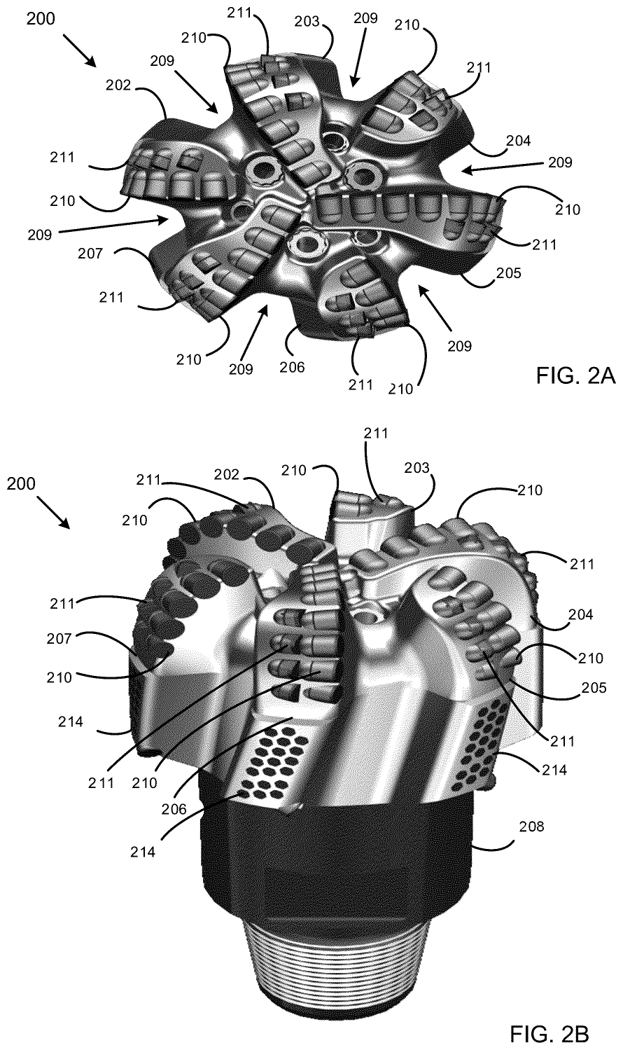

FIGS. 2A-2B are an overhead view and an isometric view, respectively, of an example drill bit, according to some embodiments. In particular, FIGS. 2A-2B depict an example drill bit 200. The drill bit 200 can be an example of the drill bit 112 of FIG. 1. As shown in this example, the drill bit 200 includes six blades 202-207, which can be integrally formed and extend from a bit body 208. The blades 202-207 are separated by flow channels 209 that may include nozzles (i.e., orifices) where drilling mud can be ejected through the drill bit 200 and into the wellbore. Primary cutters 210, backup cutters 211, and depth of cut controllers (DOCCs) may be mounted on the blades 202-207. During drilling, the face of the primary cutters 210 and backup cutters 211 can be in contact with and cut and/or shear the rock of the subsurface formation to create and extend a wellbore. In some instances, the face of the primary cutters 210 may be extended a greater distance from the blades 202-207 than the backup cutters 211 such that only the primary cutters 210 can be in contact with the rock of the subsurface formation. During drilling, the primary cutters 210 may become worn or broken such that one or more of the backup cutters 211 can then be in contact with the rock of the subsurface formation. Many factors including orientation, shape, type, and density of the cutters may vary depending on the design of the drill bit 200. Other drill bit characteristics including the number of blades, the shape of the blades, etc. may vary depending on the subsurface formation environment that the drill bit 200 may drill. Pads 214 may extend from the side of the blades 202-207. The pads 214 may help maintain the size of the wellbore to a full gauge diameter, particularly when cutters become dull and become under gauge.

### Example Operations

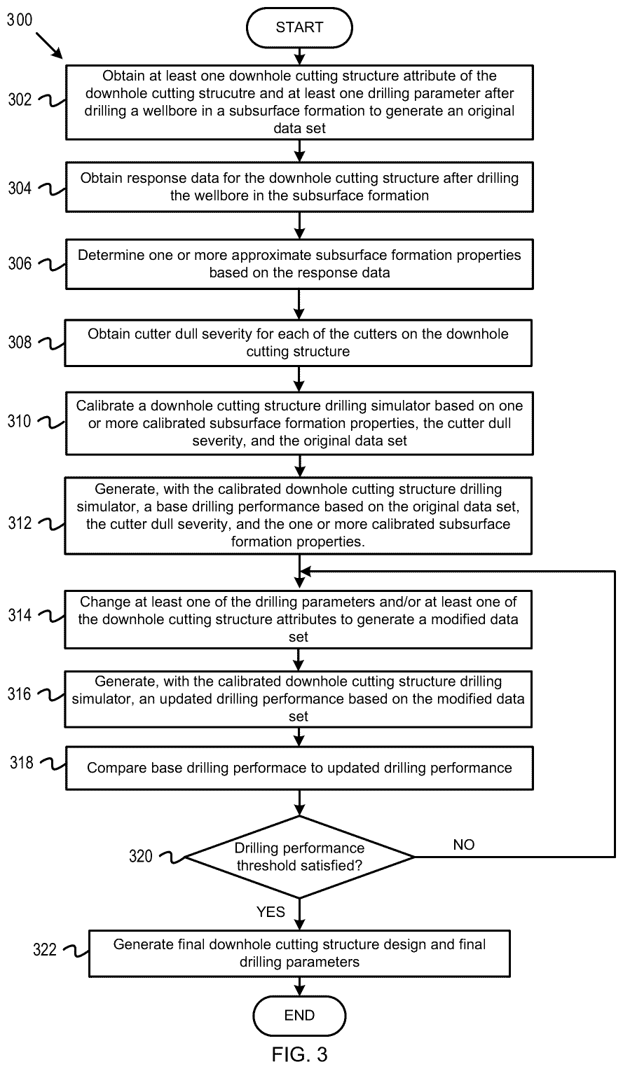

Example operations for designing a downhole cutting structure based on computer simulations of the drilling performance of the downhole cutting structure are now described in reference to FIGS. 3-11. This section describes operations associated with some implementations of the invention. In the discussion below, the flow diagrams may be described with reference to the example system presented above. In certain implementations, the operations are performed by executing instructions residing on machine-readable media (e.g., software), while in other implementations, the operations are performed by hardware and/or other logic (e.g., firmware). In some implementations, the operations are performed in series, while in other implementations, one or more of the operations can be performed in parallel. Moreover, some implementations perform less than all the operations shown in the flow diagrams.

FIG. 3 depicts a flowchart of example operations to generate a final downhole cutting structure design and/or final drilling parameters, according to some embodiments. Operations of the flowchart 300 of FIG. 3 are described in reference to the computer 170 of FIG. 1. The computer 170 may perform any or all of the operations described with reference to FIG. 3. Operations of the flowchart 300 start at block 302.

At block 302, at least one downhole cutting structure attribute of the downhole cutting structure and at least one drilling parameter may be obtained after drilling a wellbore in a subsurface formation to generate an original dataset. For example, with reference to FIG. 1, a processor of the computer 170 can perform this operation. Downhole cutting structure attributes may include characteristics of the downhole cutting structure design including number of blades, the drill bit profile, etc. Downhole cutting structure attributes may also include characteristics of the cutters on the downhole cutting structure including cutter shape, material, back rake angle, etc. Drilling parameters may include the downhole cutting structure rotation, measured in rotations-per-minute (RPM), weight-on-bit (WOB), etc. In some embodiments, the rate-of-penetration (ROP) measured at the surface may be measured in accordance with the RPM and WOB. Each of the drilling parameters may be obtained along the drilling depth of the wellbore. The drilling parameters may be measured in various depths intervals such as every foot, 5 feet, etc. or in various time intervals such as every 30 seconds, 1 minute, 1 hour, etc.

In some embodiments, only a portion of a wellbore may be drilled by the downhole cutting structure before obtaining the drilling parameters and downhole cutting structure attributes. For example, a drill bit may have been utilized to drill a certain depth interval of a wellbore, such as the first 9,000 feet, or a depth interval corresponding to one or more subsurface formations. Additionally, the drill bit may have been utilized to drill a section of the wellbore such as the vertical section, tangent section, curve section, horizontal section, etc.

At block 304, response data for a downhole cutting structure may be obtained after drilling the wellbore in the subsurface formation. For example, with reference to FIG. 1, a processor of the computer 170 can perform this operation. Response data may indicate how the downhole cutting structure interacts with the subsurface formation in accordance with the drilling parameters and downhole cutting structure attributes. Response data may include downhole measurements including downhole weight-on-bit (WOB), downhole torque-on-bit (TOB), downhole cutting structure rotation speed measured in rotations-per-minute (RPM). Vibration measurements of the downhole cutting structure such as downhole axial vibrations, downhole lateral vibrations, downhole torsional vibrations may be included in the response data. In some embodiments, ROP measured at surface may be added to the response data. For example, the ROP measured at each drilling depth may be combined with the response data at the corresponding drilling depths. Similar to the drilling parameters, the response data may be obtained at various depth intervals such as every foot, every 5 ft, etc.

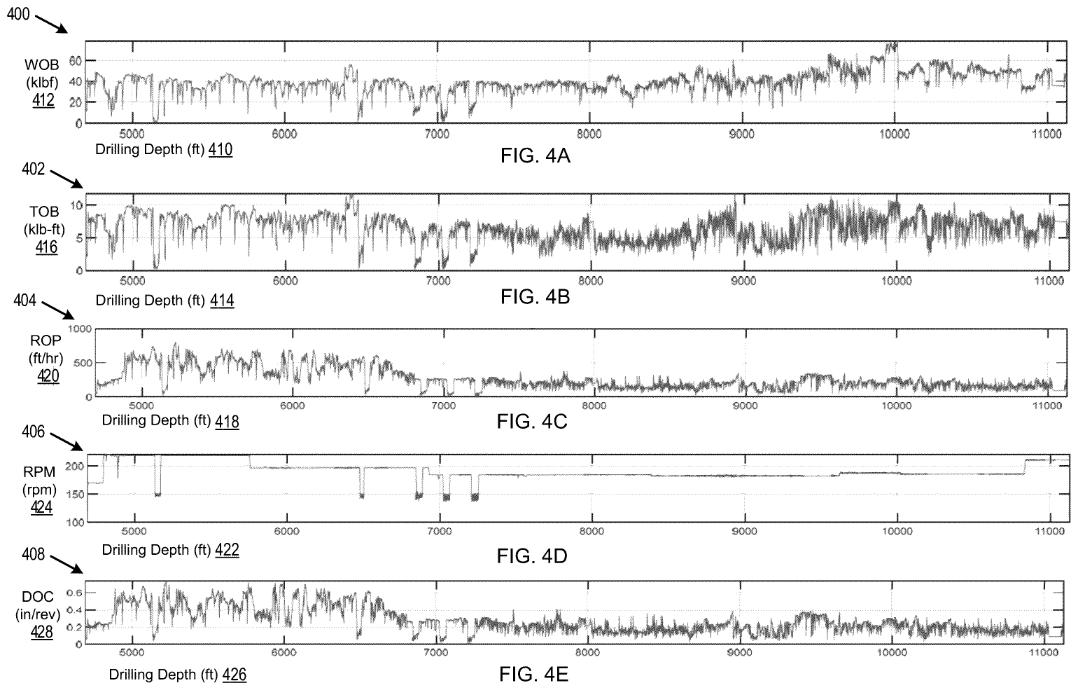

To help illustrate, FIGS. 4A-4E depict example graphs of possible response data, according to some embodiments. In FIG. 4A, the graph 400 depicts the downhole WOB and includes an x-axis 410 and a y-axis 412. The x-axis 410 is the drilling depth having units in feet (ft). The y-axis 412 is the WOB measured at the downhole cutting structure and has units in kilo pound force (klbf). In FIG. 4B, the graph 402 depicts the downhole TOB and includes an x-axis 414 and a y-axis 416. The x-axis 414 is the drilling depth having units in feet (ft). The y-axis 416 is the TOB measured at the downhole cutting structure and has units in kilo pound feet (klb-ft). In FIG. 4C, the graph 404 depicts the ROP from the drilling parameters and includes an x-axis 418 and a y-axis 420. The x-axis 418 is the drilling depth having units in feet (ft). The y-axis 420 is the ROP having units in feet per hour (ft/hr). In FIG. 4D, the graph 406 depicts the downhole cutting structure rotation frequency and includes an x-axis 422 and a y-axis 424. The x-axis 422 is the drilling depth having units in feet (ft). The y-axis 424 is the RPM of the downhole cutting structure having units in rotations per minute (rpm). In FIG. 4E, the graph 408 depicts the depth of cut of the cutters per rotation of the downhole cutting structure and includes an x-axis 426 and a y-axis 428. The x-axis 426 is the drilling depth having units in feet (ft). The y-axis 428 is the depth of cut (DOC) having units in inches per revolution (in/rev).

Returning to FIG. 3, at block 306, one or more approximate subsurface formation properties may be determined based on the response data. For example, with reference to FIG. 1, a processor of the computer 170 can perform this determination. The approximate subsurface formation properties may include the approximate rock strength, such as unconfined compressive strength (UCS) and confined compressive strength (CCS), and the friction angle. The approximate subsurface formation properties may indicate the strength of the subsurface formation. In some embodiments, other characteristics of the subsurface formation may be considered when determining the approximate subsurface formation properties. For example, the lithology of the subsurface formation, pressure, and temperature, may be utilized to determine the approximate subsurface formation properties.

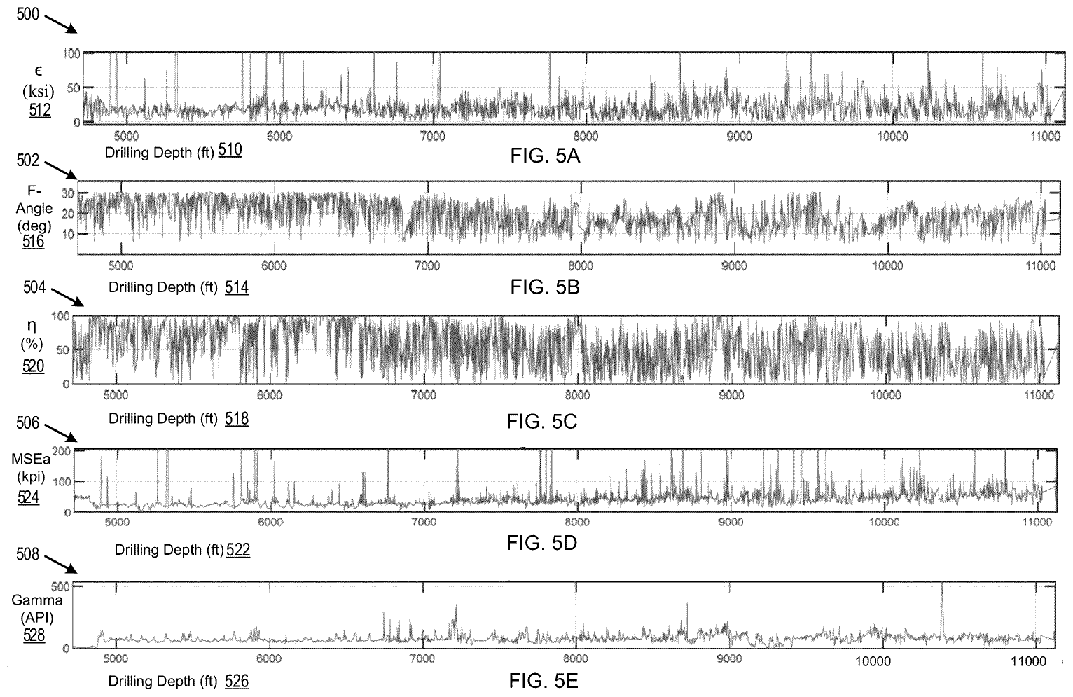

To help illustrate, FIGS. 5A-5E depict example graphs of possible subsurface formation properties, according to some embodiments. In FIG. 5A, the graph 500 depicts the estimated CCS and includes an x-axis 510 and a y-axis 512. The x-axis 510 is the drilling depth having units in feet (ft). The y-axis 512 is the CCS (ϵ) having units in kilo pounds per square inch (ksi). In FIG. 5B, the graph 502 depicts the downhole friction angle and includes an x-axis 514 and a y-axis 516. The x-axis 514 is the drilling depth having units in feet (ft). The y-axis 516 is the friction angle having units in degrees (deg). In FIG. 5C, the graph 504 depicts the drilling efficiency and includes an x-axis 518 and a y-axis 520. The x-axis 518 is the drilling depth having units in feet (ft). The y-axis 520 is the drilling efficiency (η) having units in percent (%). In FIG. 5D, the graph 506 depicts the mechanical specific energy and includes an x-axis 522 and a y-axis 524. The x-axis 522 is the drilling depth having units in feet (ft). The y-axis 524 is the mechanical specific energy (MSE) having units in kilo pounds per inch (kpi). In FIG. 5E, the graph 508 depicts the subsurface formation and includes an x-axis 526 and a y-axis 528. The x-axis 526 is the drilling depth having units in feet (ft). The y-axis 528 is the gamma measurement of the subsurface formation having units in API.

Returning to FIG. 3, at block 308, the cutter dull severity for each of the cutters on the downhole cutting structure may be obtained. For example, with reference to FIG. 1, a processor of the computer 170 can perform this operation. Cutter dull severity may include the severity in which each of the cutters are worn and/or damaged. For example, the cutter dull severity may be based on the wear depth of each element (including primary cutters, backup cutters, DOCCs, and pads) after the downhole cutting structure has drilled the wellbore. In some embodiments, the downhole cutting structure may be scanned to determine dull severity of each cutter after drilling at least a portion of the wellbore. In some embodiments, the downhole cutting structure may be scanned with an automated digital grading system to determine dull severity of each primary cutter. The downhole cutting structure may also be scanned manually or by other digital systems that may require manual intervention. Each element of the downhole cutting structure may be scanned to determine the respective dull severity. Dull severity comprises comparing the cutter characteristics after the downhole cutting structure is used to drill the wellbore to the cutter characteristics before being used. A dull severity can include the amount of cutter material remaining, the shape of the remaining cutter, etc. The shape may signify if the cutter was worn, broken, or chipped. The integrity of the cutter can be measured such as if the cutter body is cracked or delaminated. The dull severity may also determine if the cutter is still in place on the downhole cutting structure.

The cutter dull severity at the drilling depths may be determined based on the final cutter dull severity of the each of the cutters. For example, the cutter dull severity at each of the intermediate drilling depths may be determined based on the initial element profile before the wellbore is drilled and the final wear depth of each element after drilling the wellbore. The cutter dull severity at the intermediate drilling depths may be determined by various methods such as linear and nonlinear interpolation between the initial element profile and the final wear depths.

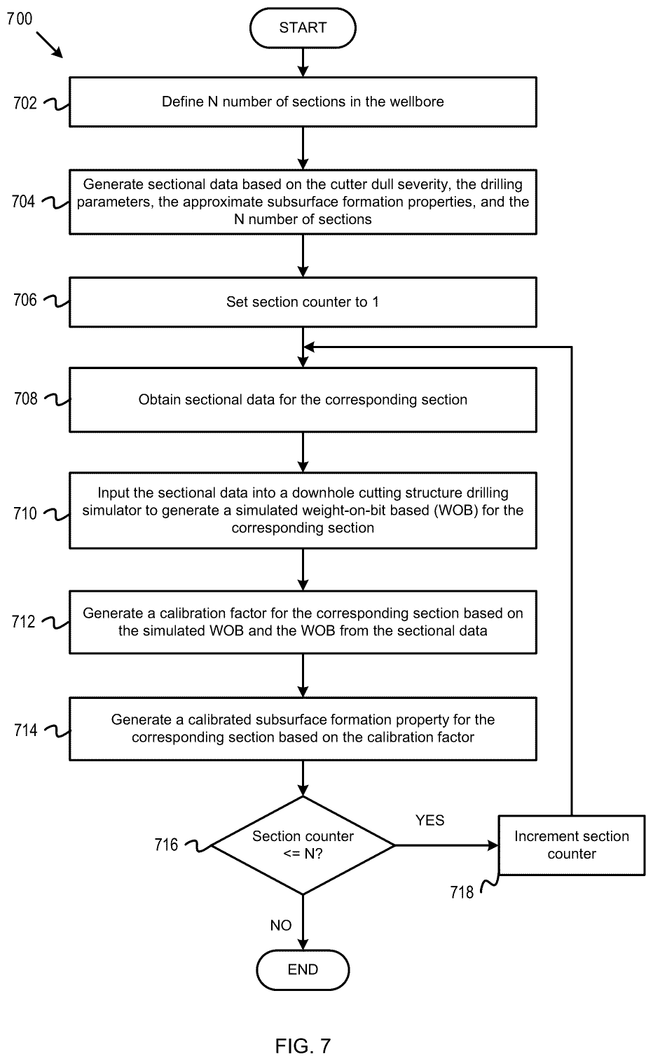

At block 310, a downhole cutting structure drilling simulator may be calibrated based on one or more calibrated subsurface formation properties, the cutter dull severity, and the original data set. For example, with reference to FIG. 1, a processor of the computer 170 can perform this calibration. A downhole cutting structure drilling simulator may be configured with the downhole cutting structure attributes. For example, the downhole cutting structure drilling simulator may be configured with the downhole cutting structure design and the cutter design of the downhole cutting structure to simulate the cutter interaction with the subsurface formation in accordance with the drilling parameters. Calibration of the downhole cutting structure drilling simulator may include calibrating the downhole cutting structure drilling simulator to the subsurface formation. For instance, a calibration matrix comprising the drilling depths, drilling parameters, ROP, response data, and one or more calibrated subsurface formation properties may be utilized to calibrate the downhole cutting structure drilling simulator. Generation of the one or more calibrated subsurface formation properties utilized to calibrate the downhole cutting structure drilling simulator is further described below in FIG. 7.

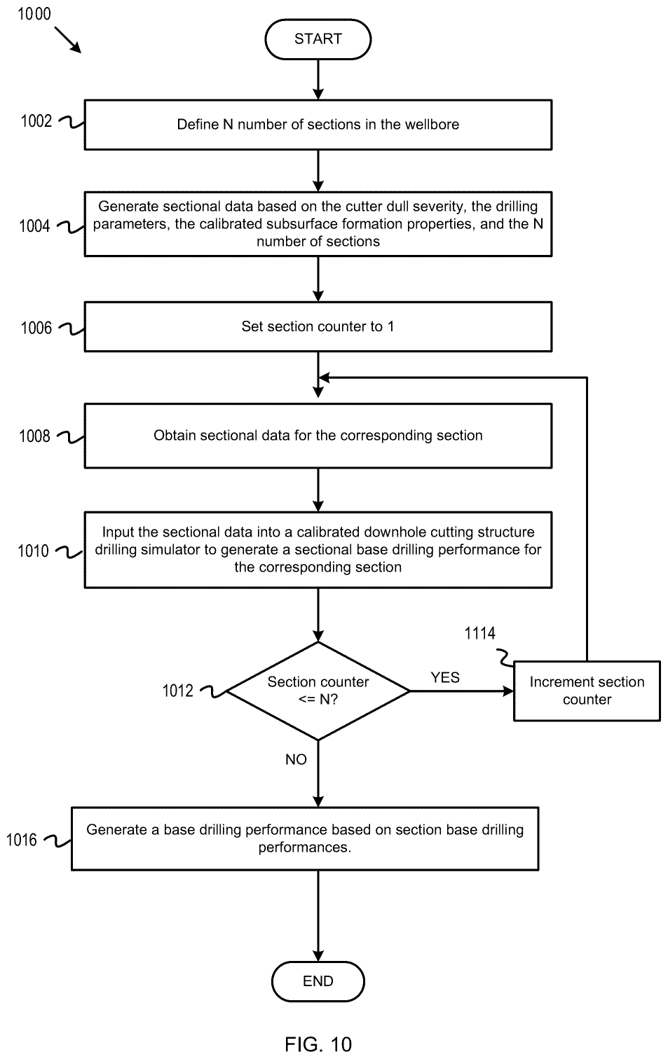

At block 312, a base drilling performance may be generated, with the calibrated downhole cutting structure drilling simulator, based on the original data set, the cutter dull severity, and the one or more calibrated subsurface formation properties. For example, with reference to FIG. 1, a processor of the computer 170 can perform this generation. In some embodiments, the base drilling performance may be a simulation of the actual drilling performance of the downhole cutting structure drilling the wellbore. The base drilling performance may include the ROP and WOB. For instance, if the wellbore is drilled while maintaining a target WOB, then the drilling performance may comprise the ROP. Additionally, if the wellbore is drilled while maintaining a target ROP, then the drilling performance may comprise the WOB. Generation of the base drilling performance is further described below in FIG. 10.

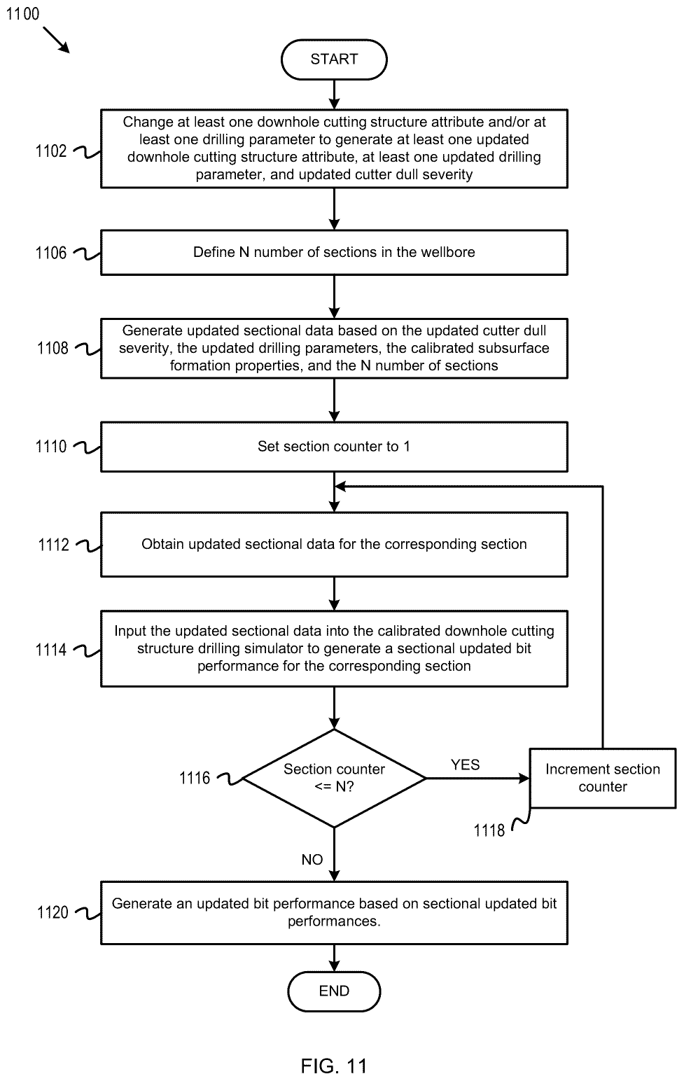

At block 314, at least one of the drilling parameters and/or at least one of the downhole cutting structure attributes may be changed to generate a modified data set. For example, with reference to FIG. 1, a processor of the computer 170 can perform this operation. Changes to the drilling parameters may include changes in the WOB and RPM. Changes to the downhole cutting structure attributes may include changes in the downhole cutting structure design and cutters design. Changes to drilling parameters and downhole cutting structure attributes are further described below in FIG. 11.

At block 316, an updated drilling performance may be generated, with the calibrated downhole cutting structure drilling simulator, based on the modified data set. For example, with reference to FIG. 1, a processor of the computer 170 can perform this generation. The updated drilling performance may indicate the drilling performance of the downhole cutting structure with the new drilling parameters and/or the new downhole cutting structure attributes determined in block 314. Similar to the base drilling performance, the updated drilling performance may include an updated ROP and/or updated WOB. Generation of the updated drilling performance is further described below in FIG. 11.

At block 318, the base drilling performance and the updated drilling performance may be compared. For example, with reference to FIG. 1, a processor of the computer 170 can perform this comparison. Comparison of the base drilling performance and the updated drilling performance may include comparing the difference between the ROP or WOB. For instance, the magnitude of the difference between the base ROP and the updated ROP may be used for the comparison. For example, an average base ROP over the drilling depths of 200 feet per hour and an average updated ROP over the drilling depths of 210 feet per hour may yield a difference of 10 feet per hour. In some embodiments, the relative difference between the base drilling performance and the updated drilling performance may be used as a comparison. For example, the average updated ROP of 210 feet per hour mentioned above may be 5% greater than the average base ROP of 200 feet per hour.

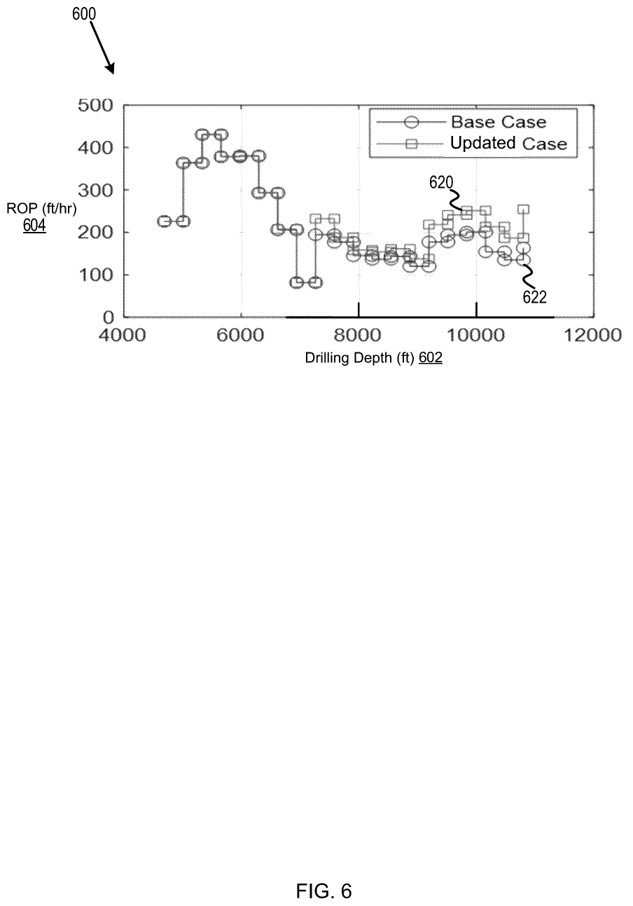

To help illustrate, FIG. 6 depicts an example graph of the drilling performances, according to some embodiments. The graph 600 includes an x-axis 602 and a y-axis 604. The x-axis is the drilling depth having units in feet (ft). The y-axis 604 is the ROP (i.e., the drilling performances as described above) having units in feet per hour (ft/hr). The base drilling performance 622 depicts the base ROP. The updated drilling performance 620 depicts the updated ROP after a change in the drilling parameters and/or the downhole cutting structure attributes are made.

Returning to FIG. 3, at block 320, a determination is made of whether a drilling performance threshold has been satisfied. For example, with reference to FIG. 1, a processor of the computer 170 can perform this determination. The drilling performance threshold may be based on the comparison of the base drilling performance and the updated drilling performance. For instance, the threshold may be satisfied if the updated ROP of the updated drilling performance is greater than the base ROP of the base drilling performance by a specified amount. For example, an ROP threshold of 10 feet per hour may be satisfied if the updated ROP is 10 feet per hour greater than the base ROP. In some embodiments, the threshold may be satisfied based on the relative change between the base drilling performance and the updated drilling performance. For example, a threshold may be satisfied if the drilling performance is 10% greater than the base drilling performance if comparing ROP. If the drilling performance threshold is not satisfied, then drilling parameters and/or downhole cutting structure attributes may be changed again to generate a new updated drilling performance. If the drilling performance threshold has been satisfied, then operations of the flowchart 300 continue to block 322. Otherwise, operations return to block 314.

At block 322, a final downhole cutting structure design and/or final drilling parameters may be generated. For example, with reference to FIG. 1, a processor of the computer 170 can perform this operation. The final downhole cutting structure design may include the downhole cutting structure design and cutter design in the modified data set generated in block 314. Additionally, the final drilling parameters may include the drilling parameters in the modified data set generated in block 314.

FIG. 7 depicts a flowchart of example operations to calibrate a drilling simulator, according to some embodiments. Operations of the flowchart 700 of FIG. 7 are described in reference to the computer 170 of FIG. 1. The computer 170 may perform any or all of the operations described with reference to FIG. 7. Operations of the flowchart 700 start at block 702.

At block 702, N number of sections in the wellbore may be defined. For example, with reference to FIG. 1, a processor of the computer 170 can perform this operation. N can be defined as one or more. The drilling depth of the wellbore may be divided into equal increments to generate the sections. For example, section 1 may correspond to the depth interval the downhole cutting structure started drilling the wellbore and section N may correspond to the depth interval the downhole cutting structure stopped drilling the wellbore. Intermediate sections may correspond to a depth interval between the first section and the N section. The N number of sections may be defined by a user or operator and/or defined by various criteria. The size of the sections may depend on the drilling depth and the N number of sections. For instance, if a drill bit begins drilling a wellbore at 0 feet measured depth (MD), ended at 10,000 feet MD, and N was defined as 10, then there would be 10 sections, each section spanning 1,000 feet. Section 1 may be from 0 feet to 1,000 feet, section 2 may be from 1,001 feet to 2,000 feet, etc., with the final section (section 10 as defined above) being from 9,001 feet to 10,000 feet. Each section may be divided into subsections. For example, a subsection may be every 5 feet, 10 feet, etc.

At block 704, sectional data may be generated based on the cutter dull severity, the drilling parameters, the approximate subsurface formation properties, and the N number of sections. For example, with reference to FIG. 1, a processor of the computer 170 can perform this generation. The sectional data may include the cutter dull severity, the drilling parameters (including the ROP), and the approximate subsurface formation properties at the drilling depths corresponding to each subsection for the sections. For example, if section i is from 5,000 feet to 5,500 feet, then the sectional data for section i may include the cutter dull severity, the drilling parameters, and the approximate subsurface formation properties corresponding to the drilling depths from 5,000 feet to 5,500 feet. In some embodiments, the data corresponding to each section may be averaged to generate the sectional data. For example, the drilling parameters corresponding to section i may be averaged over the section i's drilling depth interval to generate the average drilling parameters for section i.

To help illustrate, FIGS. 8A-8E depict example graphs of sectional data, according to some embodiments. In FIG. 8A, the graph 800 depicts the average WOB for each section (e.g., section 830) and includes an x-axis 810 and a y-axis 812. The x-axis 810 is the drilling depth having units in feet (ft). The y-axis 812 is the average WOB having units in kilo pound force (klbf). In FIG. 8B, the graph 802 depicts the average TOB for each section and includes an x-axis 814 and a y-axis 816. The x-axis 814 is the drilling depth having units in feet (ft). The y-axis 816 is the average TOB for each section having units in kilo pound feet (klb-ft). In FIG. 8C, the graph 804 depicts the average ROP for each section and includes an x-axis 818 and a y-axis 820. The x-axis 818 is the drilling depth having units in feet (ft). The y-axis 820 is the average ROP for each section having units in feet per hour (ft/hr). In FIG. 8D, the graph 806 depicts the average downhole cutting structure rotation frequency for each section and includes an x-axis 822 and a y-axis 824. The x-axis 822 is the drilling depth having units in feet (ft). The y-axis 824 is the average RPM of the downhole cutting structure for each section having units in rotations per minute (rpm). In FIG. 8E, the graph 808 depicts the average rock strength 840 and the average MSE 842 for each section and includes an x-axis 826 and a y-axis 828. The x-axis 826 is the drilling depth having units in feet (ft). The y-axis 828 is the average rock strength for each section having units in inches per revolution (in/rev).

Returning to FIG. 7, at block 706, the section counter may be set to 1. For example, with reference to FIG. 1, a processor of the computer 170 can perform this operation. The section counter may be set to 1 to begin operations of calibrating the downhole cutting structure drilling simulator to the subsurface formation.

At block 708, the sectional data for the corresponding section may be obtained. For example, with reference to FIG. 1, a processor of the computer 170 can perform this operation. For instance, the sectional data for the corresponding section may include the cutter dull severity, the drilling parameters, and the approximate subsurface property. Drilling parameters may include the average RPM, average WOB, and average ROP at the corresponding drilling depths. The approximate subsurface property may include the confined compressive strength (CCS) at the corresponding drilling depths.

At block 710, the sectional data may be input into a downhole cutting structure drilling simulator to generate a simulated WOB for the corresponding sections. For example, with reference to FIG. 1, a processor of the computer 170 can perform this generation. The downhole cutting structure drilling simulator may be configured to generate a simulated WOB to maintain the ROP provided in the drilling parameters of the sectional data given the downhole cutting structure attributes, cutter dull severity, RPM of the downhole cutting structure, and the subsurface formation CCS.

At block 712, a calibration factor may be generated for the corresponding section based on the simulated WOB and the WOB from the sectional data. For example, with reference to FIG. 1, a processor of the computer 170 can perform this generation. The WOB provided in the drilling parameters of the sectional data may indicate the actual WOB while drilling the respective section of the wellbore. To accurately simulate the drilling operation with the downhole cutting structure, a calibration factor may be generated, for the downhole cutting structure drilling simulator, based on the simulated WOB and the WOB from the sectional data. In some embodiments, the calibration factor may be generated by dividing the WOB from the sectional data by the simulated WOB.

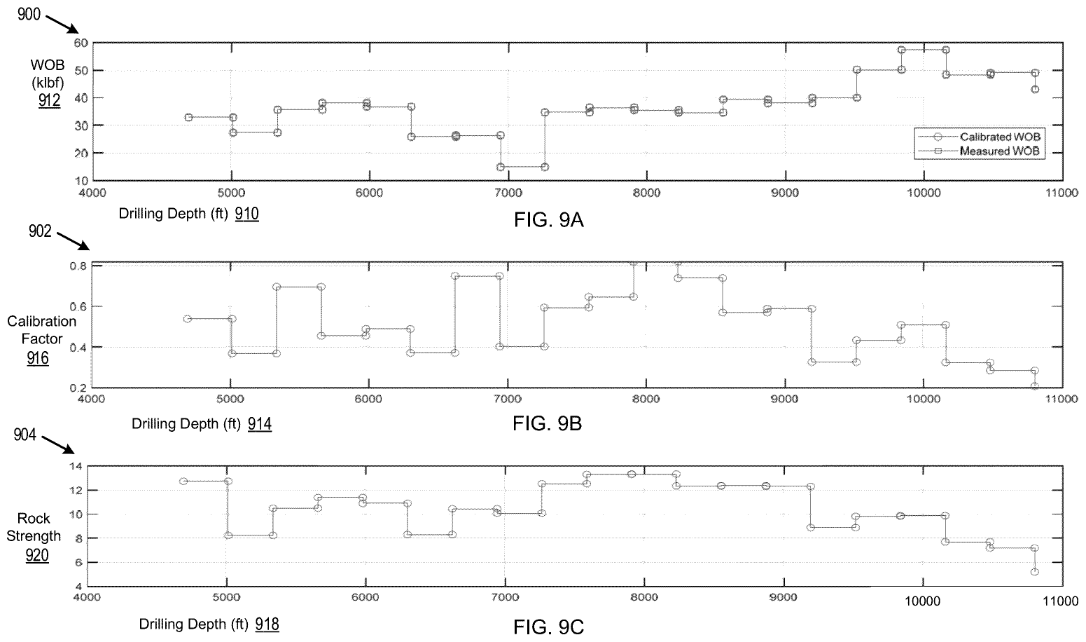

At block 714, a calibrated subsurface formation property may be generated for the corresponding section based on the calibration factor. For example, with reference to FIG. 1, a processor of the computer 170 can perform this generation. The calibration factor may be applied to the approximate subsurface formation property to generate the calibrated subsurface formation property. For example, the subsurface formation CCS may be multiplied by the calibration factor to generate a calibrated CCS for the corresponding section. To help illustrate, FIGS. 9A-9C depict example graphs for calibrating the subsurface property, according to some embodiments. In FIG. 9A, the graph 900 depicts the average measured WOB for each section and includes an x-axis 910 and a y-axis 912. The x-axis 910 is the drilling depth having units in feet (ft). The y-axis 912 is the average measured WOB for each section having units in kilo pound force (klbf). In FIG. 9B, the graph 902 depicts the calibration factor for each section and includes an x-axis 914 and a y-axis 916. The x-axis 914 is the drilling depth having units in feet (ft). The y-axis 916 is the calibration factor for each section and may be unitless. In FIG. 9C, the graph 904 depicts the calibrated subsurface formation property for each section and includes an x-axis 918 and a y-axis 920. The x-axis 918 is the drilling depth having units in feet (ft). The y-axis 920 is the calibrated rock strength for each section having units in kilo pounds per square inch (ksi)

At block 716, a determination is made of whether the section step counter is equal to N. For example, with reference to FIG. 1, a processor of the computer 170 can make this determination. If section step counter is equal to N, then operations of the flowchart 700 are complete. The calibrated subsurface properties for each of the sections may be utilized to calibrate the downhole cutting structure drilling simulator as described in block 310 of flowchart 300. For example, the calibrated subsurface properties may be utilized in the calibration matrix to calibrate the downhole cutting structure drilling simulator to the subsurface formation. If the section step counter is less than N, operations of the flowchart 700 continue at block 728.

At block 718, the increment section counter is incremented by one. For example, with reference to FIG. 1, a processor of the computer 170 can perform this operation. Operations of the flowchart 700 then return to the operation at block 708 to generate the calibrated subsurface formation property at the proceeding section.

FIG. 10 depicts a flowchart of example operations to generate a base drilling performance, according to some embodiments. Operations of the flowchart 1000 of FIG. 10 are described in reference to the computer 170 of FIG. 1. The computer 170 may perform any or all of the operations described with reference to FIG. 10. Operations of the flowchart 1000 start at block 1002.

At block 1002, N number of sections in the wellbore may be defined. For example, with reference to FIG. 1, a processor of the computer 170 can perform this operation. N can be defined as one or more. The N number of sections may be the N number of sections defined in block 702 of FIG. 7.

At block 1004, sectional data may be generated based on the cutter dull severity, the drilling parameters, the calibrated subsurface formation properties, and the N number of sections. For example, with reference to FIG. 1, a processor of the computer 170 can perform this generation. The sectional data may be the sectional data obtained in block 704 of FIG. 7. Additionally, in place of the approximate subsurface formation property, the sectional data may include the calibrated subsurface formation property for the corresponding sections. Accordingly, the sectional data may include the cutter dull severity, the drilling parameters, and the calibrated subsurface formation property for the corresponding sections.

At block 1006, the section counter may be set to 1. For example, with reference to FIG. 1, a processor of the computer 170 can perform this operation. The section counter may be set to 1 to begin operations of generating, with the calibrated downhole cutting structure drilling simulator, the base drilling performance for each of the N sections.

At block 1008, the sectional data for the corresponding section may be obtained. For example, with reference to FIG. 1, a processor of the computer 170 can perform this operation. For instance, the sectional data for the corresponding section may include the cutter dull severity, the drilling parameters, and the calibrated subsurface property. Drilling parameters may include the average RPM, average WOB, and average ROP at the corresponding drilling depths. The calibrated subsurface property may include the calibrated CCS at the corresponding drilling depths.

At block 1010, the sectional data may be input into the calibrated downhole cutting structure drilling simulator to generate a sectional base drilling performance for the corresponding section. For example, with reference to FIG. 1, a processor of the computer 170 can perform this generation. The calibrated downhole cutting structure drilling simulator may be calibrated with the downhole cutting structure attributes as described in FIG. 3. The calibrated downhole cutting structure drilling simulator may be calibrated with the calibrated subsurface formation property as described in FIG. 7. The calibrated downhole cutting structure drilling simulator may be configured to generate the base drilling performance for the corresponding section based on the mode of drilling operation in which the wellbore was drilled in. For instance, the wellbore may have been drilled by maintaining a target ROP. Thus, the WOB may fluctuate to maintain the target ROP. Accordingly, the calibrated downhole cutting structure drilling simulator may generate a base ROP as the base drilling performance based on the WOB and RPM of the drilling parameters for the corresponding section in addition to the cutter dull severity and calibrated subsurface formation property for the corresponding section. In some embodiments, the wellbore may have been drilled by maintaining a target WOB. Accordingly, the ROP and RPM of the drilling parameters for the corresponding section in addition to the cutter dull severity and calibrated subsurface formation property for the corresponding section may be input into the calibrated downhole cutting structure drilling simulator to generate a base drilling performance comprising a base WOB. The base drilling performance may also include the attributes such as drilling time of the downhole cutting structure. For instance, the drilling time may be generated based on the ROP and the total depth drilled with the downhole cutting structure.

At block 1012, a determination is made of whether the section step counter is equal to N. For example, with reference to FIG. 1, a processor of the computer 170 can make this determination. If section step counter is equal to N, then operations proceed to block 1016. Otherwise, operations of the flowchart 1000 continue at block 1014.

At block 1014, the increment section counter is incremented by one. For example, with reference to FIG. 1, a processor of the computer 170 can perform this operation. Operations of the flowchart 1000 then return to the operation at block 1008 to generate the base drilling performance for the proceeding section.

At block 1016, a base drilling performance may be generated based on the sectional base drilling performances. For example, with reference to FIG. 1, a processor of the computer 170 can perform this operation. The base drilling performance may include the conglomeration of sectional base drilling performances. The base drilling performance may indicate the drilling performance of the downhole cutting structure over the entire drilling depth as the wellbore was drilled. Operations of flowchart 1000 are complete after block 1016

FIG. 11 a flowchart of example operations to generate an updated drilling performance, according to some embodiments. Operations of the flowchart 1100 of FIG. 11 are described in reference to the computer 170 of FIG. 1. The computer 170 may perform any or all of the operations described with reference to FIG. 11. Operations of the flowchart 1100 start at block 1102.

At block 1102, at least one downhole cutting structure attribute and/or at least one drilling parameter may be changed to generate at least one updated drilling attribute, at least one updated drilling parameter, and an updated cutter dull severity. For example, with reference to FIG. 1, a processor of the computer 170 can perform this operation. Changing a downhole cutting structure attribute may include changing the downhole cutting structure design. For example, the number of blades may be increased or decreased, the drill bit profile may be changed, etc. Changes in the downhole cutting structure design may be based on the response data. For example, the downhole drill bit vibration measurements may indicate the drill bit experienced stick-slip while drilling. The downhole cutting structure design may be changed by adjusting the DOCCs to potentially mitigate the stick-slip and increase the drill bit's drilling efficiency. Changing a downhole cutting structure attribute may also include changing at least one of the cutter designs. For example, at least one of the cutters may be upgraded with better impact resistance, the back rake angle may be adjusted, the cutter chamfer may be adjusted, etc. In some embodiments, the changes to the cutter design may be based on the stability map. The stability map may be generated based on the drilling parameters and downhole cutting structure vibration measurements. For example, the cutter design may be adjusted if the stability map indicates vibrations in the drill bit in accordance with the drilling parameters. If at least one of the cutters has been changed, then the cutter dull severity of the respective cutters may be changed based on the changes to the cutters to generate an updated cutter dull severity. For example, if the cutter's impact resistance is upgraded, then the cutter dull severity for each cutter may be updated to reflect the increase in resistance to impact damage or to wear (i.e., the cutters may be less damaged or worn after drilling). Changing drilling parameters may include increasing or decreasing the RPM and WOB. For example, if the vibrations in the response data are above a threshold (i.e., according to a stability map), then the WOB may be decreased to reduce the vibrations on the downhole cutting structure.

At block 1106, N number of sections in the wellbore may be defined. For example, with reference to FIG. 1, a processor of the computer 170 can perform this operation. N can be defined as one or more. The N number of sections may be the N number of sections defined in block 702 of FIG. 7 and block 1002 of FIG. 10.

At block 1108, updated sectional data may be generated based on the updated cutter dull severity, the updated drilling parameters, the calibrated subsurface formation properties, and the N number of sections. For example, with reference to FIG. 1, a processor of the computer 170 can perform this generation. The sectional data includes the updated cutter dull severity, the updated drilling parameters, the calibrated subsurface formation properties corresponding to each of the sections. In some embodiments, the updated sectional data may include the original sectional data (as described in block 704 of FIG. 7 and block 1004 of FIG. 10) if no changes were made to downhole cutting structure attributes and/or drilling parameters. For example, if no changes were made to the drilling parameters, then the updated sectional data may include the sectional drilling parameters described in FIGS. 7 and 10.

At block 1110, the section counter may be set to 1. For example, with reference to FIG. 1, a processor of the computer 170 can perform this operation. The section counter may be set to 1 to begin operations of generating, with the calibrated downhole cutting structure drilling simulator, the updated drilling performance for each of the N sections.

At block 1112, the updated sectional data for the corresponding section may be obtained. For example, with reference to FIG. 1, a processor of the computer 170 can perform this operation. For instance, the updated sectional data for the corresponding section may include the updated cutter dull severity, the updated drilling parameters, and the calibrated subsurface property. The calibrated subsurface property may include the calibrated CCS at the corresponding drilling depths.

At block 1114, the updated sectional data may be input into the calibrated downhole cutting structure drilling simulator to generate a sectional updated drilling performance for the corresponding section. For example, with reference to FIG. 1, a processor of the computer 170 can perform this generation. The calibrated downhole cutting structure drilling simulator may be calibrated with the downhole cutting structure attributes as described in FIG. 3. The calibrated downhole cutting structure drilling simulator may be calibrated with the calibrated subsurface formation property as described in FIG. 7. As described in FIG. 10, the calibrated downhole cutting structure drilling simulator may be configured to generate the updated drilling performance for the corresponding section based on the mode of drilling operation in which the wellbore was drilled in. For instance, the updated drilling performance may include an updated ROP or an updated WOB depending on the drilling mode. The updated drilling performance may also include the attributes such as drilling time of the downhole cutting structure. For instance, the updated drilling time may be generated based on the updated ROP and the total depth drilled with the downhole cutting structure.

At block 1116, a determination is made of whether the section step counter is equal to N. For example, with reference to FIG. 1, a processor of the computer 170 can make this determination. If section step counter is equal to N, then operations proceed to block 1120. Otherwise, operations of the flowchart 1100 continue at block 1118.

At block 1118, the increment section counter is incremented by one. For example, with reference to FIG. 1, a processor of the computer 170 can perform this operation. Operations of the flowchart 1100 then return to the operation at block 1112 to generate the updated drilling performance for the proceeding section.

At block 1120, an updated drilling performance may be generated based on the sectional updated drilling performances. For example, with reference to FIG. 1, a processor of the computer 170 can perform this operation. The updated drilling performance may comprise a conglomeration of sectional base drilling performances. Operations of flowchart 1100 are complete after block 1120.

### Example Multi-Well System

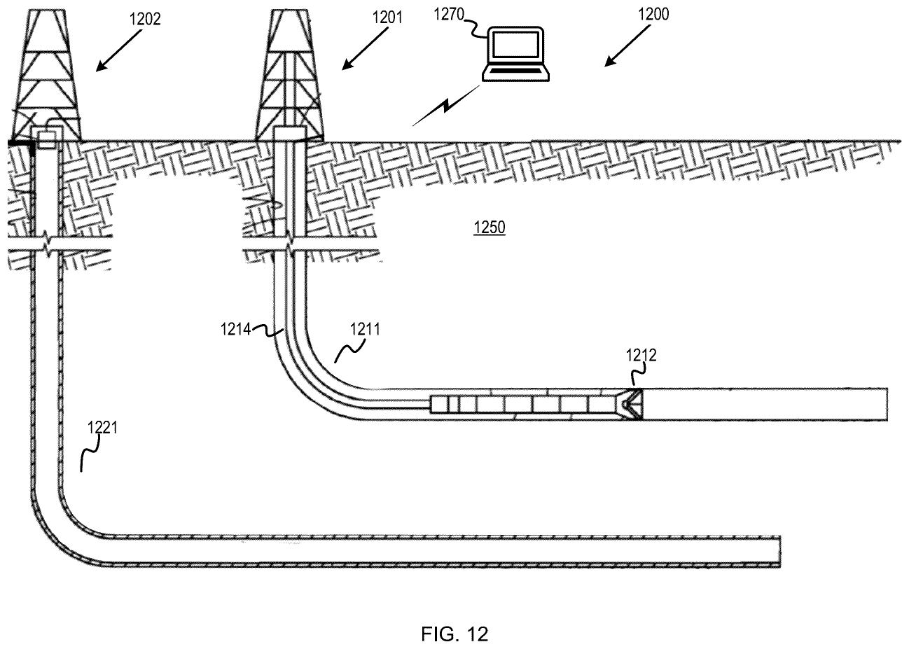

FIG. 12 depicts an example multi-well system, according to some embodiments. In particular, FIG. 12 is a schematic of a multi-well system 1200 that includes a well system 1201 and an offset well system 1202. Well system 1201 may include a drill sting 1214 having a drill bit 1212 disposed in a wellbore 1211 for drilling the wellbore 1211 in a subsurface formation 1250. Offset well system 1202 may include an offset wellbore 1221 that is drilled in subsurface formation 1250. In the example illustration, the wellbore 1211 and the offset wellbore 1221 are drilled in the same subsurface formations and therefore the drill bit 1212 may experience similar bit-rock interactions as that of a drill bit (not shown) used to drill the offset wellbore 1221. In some instances, the wellbore 1211 and the offset wellbore 1221 may not be drilled in the same subsurface formation, but in different formations that can have similar rock properties. The drill bit 1212 is an example downhole cutting structure that can be designed as described herein based on simulations performed using the downhole cutting structure and drilling parameters used to drill the offset wellbore 1221. Additionally, the downhole cutting structure attributes and drilling parameters used to drill the wellbore 1211 may be determined as described herein based on simulations performed using the drilling parameters and downhole cutting structure attributes used to drill the offset wellbore 1221.

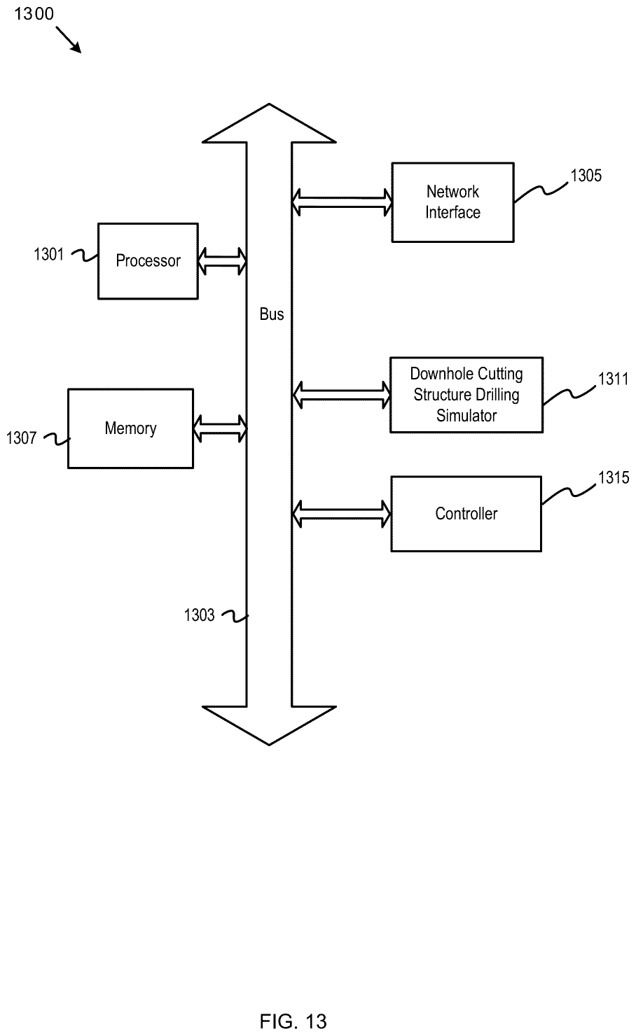

The multi-well system 1200 includes a computer 1270 that may be communicatively coupled to other parts of the multi-well system 1200. The computer 1270 can be local or remote to the drilling platform of well system 1201 or offset well system 1202. A processor of the computer 1270 may have performed simulations and generate downhole cutting structure attributes and drilling parameters (as further described herein). In some embodiments, the processor of the computer 1270 may control drilling operations of the well system 1201 or subsequent drilling operations of other wellbores, such as the offset well system 1202. An example of the computer 1270 is depicted in FIG. 13, which is further described below.

The flowcharts are provided to aid in understanding the illustrations and are not to be used to limit scope of the claims. The flowcharts depict example operations that can vary within the scope of the claims. Additional operations may be performed; fewer operations may be performed; the operations may be performed in parallel; and the operations may be performed in a different order. For example, the operations depicted in blocks 312-318 of flowchart 300 can be performed in parallel or concurrently. With respect to FIGS. 3-11, a downhole cutting structure drilling simulator is not necessary. It will be understood that each block of the flowchart illustrations and/or block diagrams, and combinations of blocks in the flowchart illustrations and/or block diagrams, can be implemented by program code. The program code may be provided to a processor of a general-purpose computer, special purpose computer, or other programmable machine or apparatus.

As will be appreciated, aspects of the disclosure may be embodied as a system, method or program code/instructions stored in one or more machine-readable media. Accordingly, aspects may take the form of hardware, software (including firmware, resident software, micro-code, etc.), or a combination of software and hardware aspects that may all generally be referred to herein as a “circuit,” “module” or “system.” The functionality presented as individual modules/units in the example illustrations can be organized differently in accordance with any one of platform (operating system and/or hardware), application ecosystem, interfaces, programmer preferences, programming language, administrator preferences, etc.

Any combination of one or more machine-readable medium(s) may be utilized. The machine-readable medium may be a machine-readable signal medium or a machine-readable storage medium. A machine-readable storage medium may be, for example, but not limited to, a system, apparatus, or device, that employs any one of or combination of electronic, magnetic, optical, electromagnetic, infrared, or semiconductor technology to store program code. More specific examples (a non-exhaustive list) of the machine-readable storage medium would include the following: a portable computer diskette, a hard disk, a random-access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a machine-readable storage medium may be any tangible medium that can contain or store a program for use by or in connection with an instruction execution system, apparatus, or device. A machine-readable storage medium is not a machine-readable signal medium.

A machine-readable signal medium may include a propagated data signal with machine readable program code embodied therein, for example, in baseband or as part of a carrier wave. Such a propagated signal may take any of a variety of forms, including, but not limited to, electro-magnetic, optical, or any suitable combination thereof. A machine-readable signal medium may be any machine-readable medium that is not a machine-readable storage medium and that can communicate, propagate, or transport a program for use by or in connection with an instruction execution system, apparatus, or device.

Program code embodied on a machine-readable medium may be transmitted using any appropriate medium, including but not limited to wireless, wireline, optical fiber cable, RF, etc., or any suitable combination of the foregoing.

Computer program code for carrying out operations for aspects of the disclosure may be written in any combination of one or more programming languages, including an object oriented programming language such as the Java® programming language, C++ or the like; a dynamic programming language such as Python; a scripting language such as Perl programming language or PowerShell script language; and conventional procedural programming languages, such as the “C” programming language or similar programming languages. The program code may execute entirely on a stand-alone machine, may execute in a distributed manner across multiple machines, and may execute on one machine while providing results and or accepting input on another machine.

The program code/instructions may also be stored in a machine-readable medium that can direct a machine to function in a particular manner, such that the instructions stored in the machine-readable medium produce an article of manufacture including instructions which implement the function/act specified in the flowchart and/or block diagram block or blocks.

### Example Computer

FIG. 13 depicts an example computer, according to some embodiments. FIG. 13 depicts a computer 1300 that includes a processor 1301 (possibly including multiple processors, multiple cores, multiple nodes, and/or implementing multi-threading, etc.). The computer 1300 includes a memory 1307. The memory 1307 may be system memory or any one or more of the above already described possible realizations of machine-readable media. The computer 1300 also includes a bus 1303 and a network interface 1305.

The computer 1300 also includes a downhole cutting structure drilling simulator 1311 and a controller 1315. The downhole cutting structure drilling simulator 1311 and the controller 1315 can perform one or more of the operations described herein. For example, the downhole cutting structure drilling simulator 1311 can perform simulations for a downhole cutting structure. The controller 1315 can perform various control operations to a wellbore operation based on the simulations. For example, the controller 1315 can modify a drilling operation based on the simulations.

Any one of the previously described functionalities may be partially (or entirely) implemented in hardware and/or on the processor 1301. For example, the functionality may be implemented with an application specific integrated circuit, in logic implemented in the processor 1301, in a co-processor on a peripheral device or card, etc. Further, realizations may include fewer or additional components not illustrated in FIG. 13 (e.g., video cards, audio cards, additional network interfaces, peripheral devices, etc.). The processor 1301 and the network interface 1305 are coupled to the bus 1303. Although illustrated as being coupled to the bus 1303, the memory 1307 may be coupled to the processor 1301.

While the aspects of the disclosure are described with reference to various implementations and exploitations, it will be understood that these aspects are illustrative and that the scope of the claims is not limited to them. In general, techniques for simulating drill bit abrasive wear and damage during the drilling of a wellbore as described herein may be implemented with facilities consistent with any hardware system or hardware systems. Many variations, modifications, additions, and improvements are possible.

Plural instances may be provided for components, operations or structures described herein as a single instance. Finally, boundaries between various components, operations and data stores are somewhat arbitrary, and particular operations are illustrated in the context of specific illustrative configurations. Other allocations of functionality are envisioned and may fall within the scope of the disclosure. In general, structures and functionality presented as separate components in the example configurations may be implemented as a combined structure or component. Similarly, structures and functionality presented as a single component may be implemented as separate components. These and other variations, modifications, additions, and improvements may fall within the scope of the disclosure.

### Example Embodiments

Embodiment #1: A method for downhole cutting structure design, the method comprising: executing a first computer-simulated drilling by at least one downhole cutting structure of a wellbore into a subsurface formation based on an original data set that includes at least one drilling parameter and at least one downhole cutting structure attribute associated with an actual drilling of the wellbore into the subsurface formation using the at least one downhole cutting structure; and recursively performing the following operations until a drilling performance threshold is satisfied, changing at least one of the at least one drilling parameter and the at least one downhole cutting structure attribute in the original data set to create a modified data set; and executing a second computer-simulated drilling by the at least one downhole cutting structure of the wellbore into the subsurface formation based and the modified data set.

Embodiment #2: The method of Embodiment #1, further comprising: receiving response data defining a response by the at least one downhole cutting structure to the actual drilling of the wellbore into the subsurface formation; and determining an approximate subsurface formation property into which the wellbore is drilled, based the response data.

Embodiment #3: The method of Embodiment #2, wherein the approximate subsurface formation property includes at least one of an unconfined compressive strength, confined compressive strength, and friction angle.

Embodiment #4: The method of Embodiments #2 or #3, wherein the response data includes a downhole weight-on-bit (WOB), a downhole torque-on-bit (TOB), a downhole cutting structure rotation frequency, and at least one downhole cutting structure vibration measurement.

Embodiment #5: The method of any one or more of Embodiments #1-4, further comprising: determining a cutter dull severity of the at least one downhole cutting structure that is a result of the actual drilling, wherein executing the first computer-simulated drilling comprises executing the first computer-simulated drilling based on the cutter dull severity, and updating the cutter dull severity based on the modified data set to create an updated cutter dull severity, wherein executing the second computer-simulated drilling comprises executing the second computer-simulated drilling based on the updated cutter dull severity.

Embodiment #6: The method of Embodiment #5, further comprising: calibrating an approximate subsurface formation property based on at least one of the cutter dull severity and the at least one drilling parameter to generate a calibrated subsurface formation property, wherein executing the first computer-simulated drilling comprises executing the first computer-simulated drilling based on the calibrated subsurface formation property, and wherein executing the second computer-simulated drilling comprises executing the second computer-simulated drilling based on the calibrated subsurface formation property.

Embodiment #7: The method of any one or more of Embodiments #1-6, further comprising: determining at least one of a final downhole cutting structure design and final drilling parameters based on the first computer-simulated drilling and the second computer-simulated drilling.

Embodiment #8: The method of any one or more of Embodiments #1-7, further comprising: separating the wellbore into one or more sections based on drilling depths of the wellbore, wherein executing the first computer-simulated drilling comprises executing the first computer-simulated drilling for each of the one or more sections, and wherein executing the second computer-simulated drilling comprises executing the second computer-simulated drilling for each of the one or more sections.

Embodiment #9: The method of any one or more of Embodiments #1-8, wherein the at least one downhole cutting structure includes at least one of a polycrystalline diamond compact (PDC) drill bit, a stand-alone reamer, and a coring bit.

Embodiment #10: The method of any one or more of Embodiments #1-9, wherein the at least one downhole cutting structure attribute comprises a cutter design and a downhole cutting structure design.

Embodiment #11: A non-transitory, computer-readable medium having instructions stored thereon that are executable by a processor to perform operations comprising: executing a first computer-simulated drilling by at least one downhole cutting structure of a wellbore into a subsurface formation based on an original data set that includes at least one drilling parameter and at least one downhole cutting structure attribute associated with an actual drilling of the wellbore into the subsurface formation using the at least one downhole cutting structure; and recursively performing the following operations until a drilling performance threshold is satisfied, changing at least one of the at least one drilling parameter and the at least one downhole cutting structure attribute in the original data set to create a modified data set; and executing a second computer-simulated drilling by the at least one downhole cutting structure of the wellbore into the subsurface formation the modified data set.

Embodiment #12: The non-transitory, computer-readable medium of Embodiment #11 further comprising: receiving response data defining a response by the at least one downhole cutting structure to the actual drilling of the wellbore into the subsurface formation; and determining an approximate subsurface formation property into which the wellbore is drilled, based on the response data.

Embodiment #13: The non-transitory, computer-readable medium of Embodiments #11 or #12, further comprising: determining a cutter dull severity of the at least one downhole cutting structure that is a result of the actual drilling, wherein executing the first computer-simulated drilling comprises executing the first computer-simulated drilling based on the cutter dull severity, and updating the cutter dull severity based on the modified data set to create an updated cutter dull severity, wherein executing the second computer-simulated drilling comprises executing the second computer-simulated drilling based on the updated cutter dull severity.

Embodiment #14: The non-transitory, computer-readable medium of Embodiment #13, further comprising: calibrating an approximate subsurface formation property based on at least one of the cutter dull severity and the at least one drilling parameter to generate a calibrated subsurface formation property, wherein executing the first computer-simulated drilling comprises executing the first computer-simulated drilling based on the calibrated subsurface formation property, and wherein executing the second computer-simulated drilling comprises executing the second computer-simulated drilling based on the calibrated subsurface formation property.

Embodiment #15: The non-transitory, computer-readable medium of any one or more of Embodiments #11-14, further comprising: determining at least one of a final downhole cutting structure design and final drilling parameters based on the first computer-simulated drilling and the second computer-simulated drilling.

Embodiment #16: The non-transitory, computer-readable medium of any one or more of Embodiments #11-15, further comprising: separating the wellbore into one or more sections based on drilling depths of the wellbore, wherein executing the first computer-simulated drilling comprises executing the first computer-simulated drilling for each of the one or more sections, and wherein executing the second computer-simulated drilling comprises executing the second computer-simulated drilling for each of the one or more sections.

Embodiment #17: A system comprising: at least one downhole cutting structure; a processor; and a computer-readable medium having instructions stored thereon that are executable by the processor to cause the processor to, execute a first computer-simulated drilling by the at least one downhole cutting structure of a wellbore into a subsurface formation an original data set that includes at least one drilling parameter and at least one downhole cutting structure attribute associated with an actual drilling of the wellbore into the subsurface formation using the at least one downhole cutting structure; and recursively perform the following operations until a drilling performance threshold is satisfied, change at least one of the at least one drilling parameter and the at least one downhole cutting structure attribute in the original data set to create a modified data set; and execute a second computer-simulated drilling by the at least one downhole cutting structure of the wellbore into the subsurface formation based on the modified data set.

Embodiment #18: The system of Embodiment #17, further comprising: receiving response data defining a response by the at least one downhole cutting structure to the actual drilling of the wellbore into the subsurface formation; and determining an approximate subsurface formation property into which the wellbore is drilled, based on the response data.

Embodiment #19: The system of Embodiments #17 or #18, further comprising: determining a cutter dull severity of the at least one downhole cutting structure that is a result of the actual drilling, wherein executing the first computer-simulated drilling comprises executing the first computer-simulated drilling based on the cutter dull severity, and updating the cutter dull severity based on the modified data set to create an updated cutter dull severity, wherein executing the second computer-simulated drilling comprises executing the second computer-simulated drilling based on the updated cutter dull severity.

Embodiment #20: The system of Embodiment #19, further comprising: calibrating an approximate subsurface formation property based on at least one of the cutter dull severity and the at least one drilling parameter to generate a calibrated subsurface formation property, wherein executing the first computer-simulated drilling comprises executing the first computer-simulated drilling based on the calibrated subsurface formation property, and wherein executing the second computer-simulated drilling comprises executing the second computer-simulated drilling based on the calibrated subsurface formation property.

Use of the phrase “at least one of” preceding a list with the conjunction “and” should not be treated as an exclusive list and should not be construed as a list of categories with one item from each category, unless specifically stated otherwise. A clause that recites “at least one of A, B, and C” can be infringed with only one of the listed items, multiple of the listed items, and one or more of the items in the list and another item not listed.

As used herein, the term “or” is inclusive unless otherwise explicitly noted. Thus, the phrase “at least one of A, B, or C” is satisfied by any element from the set {A, B, C} or any combination thereof, including multiples of any element.

1. A method for downhole cutting structure design, the method comprising:
executing a first computer-simulated drilling by at least one downhole cutting structure of a wellbore into a subsurface formation based on an original data set that includes at least one drilling parameter and at least one downhole cutting structure attribute associated with an actual drilling of the wellbore into the subsurface formation using the at least one downhole cutting structure; and
recursively performing the following operations until a drilling performance threshold is satisfied,
changing at least one of the at least one drilling parameter and the at least one downhole cutting structure attribute in the original data set to create a modified data set; and
executing a second computer-simulated drilling by the at least one downhole cutting structure of the wellbore into the subsurface formation based and the modified data set.

2. The method of claim 1, further comprising:
receiving response data defining a response by the at least one downhole cutting structure to the actual drilling of the wellbore into the subsurface formation; and
determining an approximate subsurface formation property into which the wellbore is drilled, based the response data.

3. The method of claim 2, wherein the approximate subsurface formation property includes at least one of an unconfined compressive strength, confined compressive strength, and friction angle.

4. The method of claim 2, wherein the response data includes a downhole weight-on-bit (WOB), a downhole torque-on-bit (TOB), a downhole cutting structure rotation frequency, and at least one downhole cutting structure vibration measurement.

5. The method of claim 1, further comprising:
determining a cutter dull severity of the at least one downhole cutting structure that is a result of the actual drilling, wherein executing the first computer-simulated drilling comprises executing the first computer-simulated drilling based on the cutter dull severity, and
updating the cutter dull severity based on the modified data set to create an updated cutter dull severity, wherein executing the second computer-simulated drilling comprises executing the second computer-simulated drilling based on the updated cutter dull severity.

6. The method of claim 5, further comprising:
calibrating an approximate subsurface formation property based on at least one of the cutter dull severity and the at least one drilling parameter to generate a calibrated subsurface formation property,
wherein executing the first computer-simulated drilling comprises executing the first computer-simulated drilling based on the calibrated subsurface formation property, and
wherein executing the second computer-simulated drilling comprises executing the second computer-simulated drilling based on the calibrated subsurface formation property.

7. The method of claim 1, further comprising:
determining at least one of a final downhole cutting structure design and final drilling parameters based on the first computer-simulated drilling and the second computer-simulated drilling.

8. The method of claim 1, further comprising:
separating the wellbore into one or more sections based on drilling depths of the wellbore,
wherein executing the first computer-simulated drilling comprises executing the first computer-simulated drilling for each of the one or more sections, and
wherein executing the second computer-simulated drilling comprises executing the second computer-simulated drilling for each of the one or more sections.

9. The method of claim 1, wherein the at least one downhole cutting structure includes at least one of a polycrystalline diamond compact (PDC) drill bit, a stand-alone reamer, and a coring bit.

10. The method of claim 1, wherein the at least one downhole cutting structure attribute comprises a cutter design and a downhole cutting structure design.

11. A non-transitory, computer-readable medium having instructions stored thereon that are executable by a processor to perform operations comprising:
executing a first computer-simulated drilling by at least one downhole cutting structure of a wellbore into a subsurface formation based on an original data set that includes at least one drilling parameter and at least one downhole cutting structure attribute associated with an actual drilling of the wellbore into the subsurface formation using the at least one downhole cutting structure; and
recursively performing the following operations until a drilling performance threshold is satisfied,
changing at least one of the at least one drilling parameter and the at least one downhole cutting structure attribute in the original data set to create a modified data set; and
executing a second computer-simulated drilling by the at least one downhole cutting structure of the wellbore into the subsurface formation the modified data set.

12. The non-transitory, computer-readable medium of claim 11 further comprising:
receiving response data defining a response by the at least one downhole cutting structure to the actual drilling of the wellbore into the subsurface formation; and
determining an approximate subsurface formation property into which the wellbore is drilled, based on the response data.

13. The non-transitory, computer-readable medium of claim 11, further comprising:
determining a cutter dull severity of the at least one downhole cutting structure that is a result of the actual drilling, wherein executing the first computer-simulated drilling comprises executing the first computer-simulated drilling based on the cutter dull severity, and
updating the cutter dull severity based on the modified data set to create an updated cutter dull severity, wherein executing the second computer-simulated drilling comprises executing the second computer-simulated drilling based on the updated cutter dull severity.

14. The non-transitory, computer-readable medium of claim 13, further comprising:
calibrating an approximate subsurface formation property based on at least one of the cutter dull severity and the at least one drilling parameter to generate a calibrated subsurface formation property,
wherein executing the first computer-simulated drilling comprises executing the first computer-simulated drilling based on the calibrated subsurface formation property, and
wherein executing the second computer-simulated drilling comprises executing the second computer-simulated drilling based on the calibrated subsurface formation property.

15. The non-transitory, computer-readable medium of claim 11, further comprising:
determining at least one of a final downhole cutting structure design and final drilling parameters based on the first computer-simulated drilling and the second computer-simulated drilling.

16. The non-transitory, computer-readable medium of claim 11, further comprising:
separating the wellbore into one or more sections based on drilling depths of the wellbore,
wherein executing the first computer-simulated drilling comprises executing the first computer-simulated drilling for each of the one or more sections, and
wherein executing the second computer-simulated drilling comprises executing the second computer-simulated drilling for each of the one or more sections.

17. A system comprising:
at least one downhole cutting structure;
a processor; and
a computer-readable medium having instructions stored thereon that are executable by the processor to cause the processor to,
execute a first computer-simulated drilling by the at least one downhole cutting structure of a wellbore into a subsurface formation an original data set that includes at least one drilling parameter and at least one downhole cutting structure attribute associated with an actual drilling of the wellbore into the subsurface formation using the at least one downhole cutting structure; and
recursively perform the following operations until a drilling performance threshold is satisfied,
change at least one of the at least one drilling parameter and the at least one downhole cutting structure attribute in the original data set to create a modified data set; and
execute a second computer-simulated drilling by the at least one downhole cutting structure of the wellbore into the subsurface formation based on the modified data set.

18. The system of claim 17, further comprising:
receiving response data defining a response by the at least one downhole cutting structure to the actual drilling of the wellbore into the subsurface formation; and
determining an approximate subsurface formation property into which the wellbore is drilled, based on the response data.

19. The system of claim 17, further comprising:
determining a cutter dull severity of the at least one downhole cutting structure that is a result of the actual drilling, wherein executing the first computer-simulated drilling comprises executing the first computer-simulated drilling based on the cutter dull severity, and
updating the cutter dull severity based on the modified data set to create an updated cutter dull severity, wherein executing the second computer-simulated drilling comprises executing the second computer-simulated drilling based on the updated cutter dull severity.

20. The system of claim 19, further comprising:
calibrating an approximate subsurface formation property based on at least one of the cutter dull severity and the at least one drilling parameter to generate a calibrated subsurface formation property,
wherein executing the first computer-simulated drilling comprises executing the first computer-simulated drilling based on the calibrated subsurface formation property, and
wherein executing the second computer-simulated drilling comprises executing the second computer-simulated drilling based on the calibrated subsurface formation property.
